(19) United States
(12) Patent Application Publication
(10) Pub. No.: US 2016/0033559 A1
(43) Pub. Date: Feb. 4, 2016

(54) OVERCURRENT DETECTING DEVICE AND OVERCURRENT DETECTING METHOD

(71) Applicant: HITACHI AUTOMOTIVE SYSTEMS, LTD., Ibaraki (JP)

(72) Inventor: Yuichi KURAMOCHI, Isesaki-shi Gunma (JP)

(73) Assignee: HITACHI AUTOMOTIVE SYSTEMS, LTD., Ibaraki (JP)

(21) Appl. No.: 14/424,081

(22) PCT Filed: Mar. 17, 2014
(86) PCT No.: PCT/JP2014/057094

§ 371 Date: Feb. 26, 2015

(30) Foreign Application Priority Data
Aug. 30, 2013 (JP) 2013-180272

(51) Int. Cl. G01R 19/165; G01R 31/34

(52) U.S. Cl. CPC G01R 19/165; G01R 31/34

(57) ABSTRACT

The present invention relates to an overcurrent detecting device and an overcurrent detecting method each of which detects an overcurrent upstream of an inverter circuit in a drive control device for an electric motor. The overcurrent is detected without providing a shunt resistor in the upstream of the inverter circuit, and miniaturization of a circuit substrate is achieved. The overcurrent detecting device calculates a current value of a power supply line from each phase current supplied to the electric motor and a power supply voltage of the inverter circuit, and detects an overcurrent, based on a current value determined from a drop voltage value by an electronic part connected to the power supply line and the current value of the power supply line.

### TECHNICAL FIELD

The present invention relates to an overcurrent detecting device and to a method for detecting an overcurrent upstream of an inverter circuit in a drive control device for an electric motor.

### BACKGROUND ART

Heretofore, as a detecting device for detecting a fault in a drive control device for an electric motor, there has been described in, for example, Patent Document 1, one using current detection resistors. In Patent Document 1, the current detection resistors are respectively provided upstream and downstream of an inverter circuit. An overcurrent due to a short circuit or a ground fault in each path in the inverter circuit is detected by changes in voltages across these current detection resistors.

### REFERENCE DOCUMENT LIST

### Patent Document

Patent Document 1: Japanese Patent Application Laid-open Publication No. H6-233450

### SUMMARY OF THE INVENTION

### Problems to be Solved by the Invention

When, however, shunt resistors are used for the current detection resistors, a large current flows through the shunt resistor on the upstream side for detecting a bus current, thereby enlarging the size of the shunt resistor and increasing a mounting area. Further, since the shunt resistor is inserted in series to a power supply line, the current capacity is required to be secured, and a wiring area increases due to difficulties in wiring layout due to the routing of the thick power supply line. A problem therefore arises in that a circuit substrate becomes large in size.

The present invention has been made in view of the above-mentioned circumstances. An object of the present invention is to provide an overcurrent detecting device and an overcurrent detecting method, each of which is capable of detecting an overcurrent without providing a shunt resistor upstream of an inverter circuit and achieving miniaturization of a circuit substrate.

### Means for Solving the Problems

Therefore, in the overcurrent detecting device and method of the present invention, a current value flowing through a power supply line is calculated from each phase current supplied to an electric motor and a power supply voltage of an inverter circuit. An overcurrent is detected based on a current value determined from a drop voltage value by an electronic part for a drive control device connected to the power supply line and the current value flowing through the power supply line.

### Effects of the Invention

According to the present invention, since an overcurrent is detected using an electronic part for a drive control device, which is provided in a power supply line of an inverter circuit, a shunt resistor in the upstream of the inverter circuit can be made unnecessary. Variations in the resistance value of the electronic part and a change in the characteristics thereof can be suppressed by calculating a current value flowing through the power supply line from each phase current supplied to an electric motor and a power supply voltage of the inverter circuit and detecting an overcurrent, based on this current value and a current value determined from a drop voltage value. It is thus possible to reduce a mounting area and a wiring area and miniaturize a circuit substrate.

### BRIEF DESCRIPTION OF THE DRAWINGS

FIG. 1 illustrates an overcurrent detecting device according to a first embodiment of the present invention, which is a circuit diagram of a drive control device for an electric motor.

FIG. 2 is a flowchart illustrating an operation for detecting an overcurrent in the circuit illustrated in FIG. 1.

FIG. 3 illustrates an overcurrent detecting device according to a second embodiment of the present invention, which is a circuit diagram of a drive control device for an electric motor.

### MODE FOR CARRYING OUT THE INVENTION

Embodiments of the present invention will hereinafter be described with reference to the drawings.

### First Embodiment

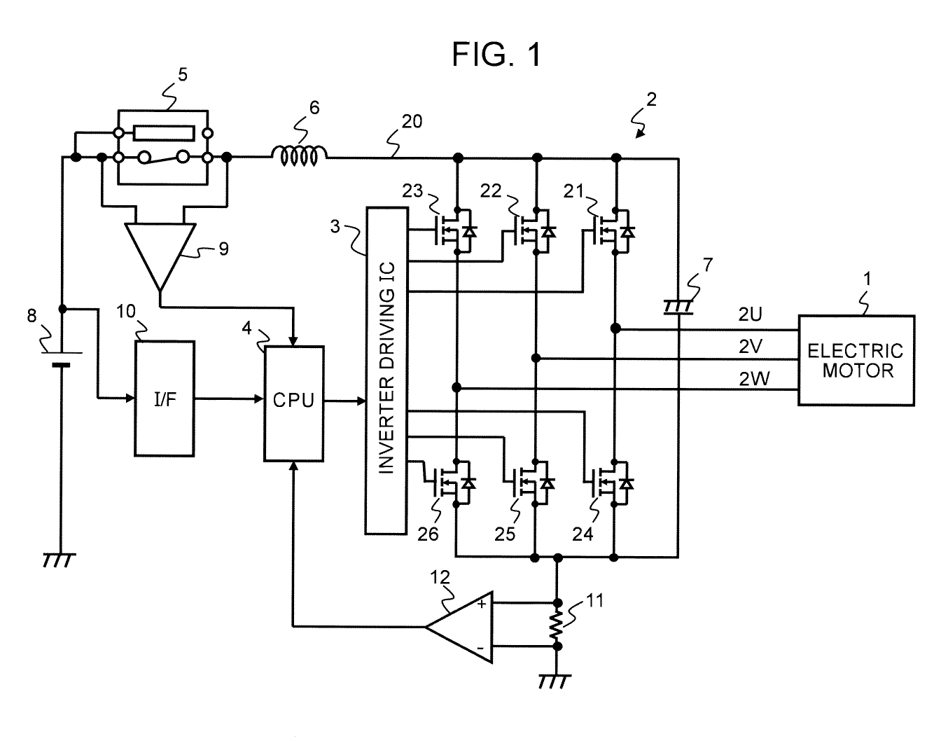

A drive control device for an electric motor illustrated in FIG. 1 is configured to include an inverter circuit 2 that drives an electric motor 1, an inverter driving IC3 that ON/OFF-controls respective MOSFETs 21 to 26 of inverter circuit 2, a CPU 4, a FS (Fail Safe) relay 5, a noise removing coil (inductor) 6, a smoothing capacitor 7 and a DC power supply 8, etc.

Also, an overcurrent detecting device is equipped with an operational amplifier 9 for drop voltage detection, an I/F (Interface) circuit 10 for inputting a power supply voltage of DC power supply 8 to CPU 4, a phase current detection resistor 11 and an operational amplifier 12, etc. Further, CPU 4 performs an arithmetic operation and determination for detecting an overcurrent, based on a drop voltage value by FS relay 5, which has been detected by operational amplifier 9, the voltage of DC power supply 8 inputted via I/F circuit 10, and the difference in potential between both ends of phase current detection resistor 11, which has been detected by operational amplifier 12.

Inverter circuit 2 has a three-phase bridge circuit configuration equipped with three sets of semiconductor elements that respectively drive a U phase, a V phase and a W phase of electric motor 1 for every phase through drive lines 2U, 2V and 2W. In the present example, the respective semiconductor elements are composed of N channel MOSFETs 21 to 26.

In MOSFETs 21 and 24, drain-source current paths are connected in series between a power supply line 20 and one end of phase current detection resistor 11, and a common connection point is connected with one end of the drive line 2U. In MOSFETs 22 and 25, drain-source current paths are connected in series between power supply line 20 and one end of phase current detection resistor 11, and a common connection point is connected with one end of the drive line 2V. Further, in MOSFETs 23 and 26, drain-source current paths are connected in series between power supply line 20 and one end of phase current detection resistor 11, and a common connection point is connected with one end of the drive line 2W. The other end of phase current detection resistor 11 is connected to a ground point (ground line).

Incidentally, diodes connected in the forward direction between the sources and drains of MOSFETs 21 to 26 are respectively parasitic diodes of these MOSFETs 21 to 26.

Smoothing capacitor 7 is connected between power supply line 20 located upstream of the inverter circuit 2 and one end of phase current detection resistor 11. This power supply line 20 is supplied with power from a positive electrode of DC power supply 8 through FS relay 5 that is an electronic part for the drive control device and coil 6. A first input terminal of operational amplifier 9 is connected to a terminal of FS relay 5, and a second input terminal of operational amplifier 9 is connected to another terminal of FS relay 5. A difference in potential therebetween, in other words, a drop voltage value is supplied from an output terminal to CPU 4. Further, the voltage of the positive electrode of DC power supply 8 is input to CPU 4 through I/F circuit 10 so that the power supply voltage is measured. First and second input terminals of operational amplifier 12 are connected to both ends of phase current detection resistor 11, and the difference in potential therebetween is supplied to CPU 4.

CPU 4 supplies a control signal to inverter driving IC3 in accordance with a program. Inverter driving IC3 supplies drive signals to gates of respective MOSFETs 21 to 26 in inverter circuit 2 to turn them ON/OFF. Thus, CPU 4 controls, e.g., vector-controls, the driving of electric motor 1.

Also, CPU 4 calculates each phase current supplied from inverter circuit 2 to electric motor 1 on the basis of the potential difference detected by operational amplifier 12 and the power supply voltage supplied through I/F circuit 10. Furthermore, CPU 4 calculates a current value flowing through power supply line 20 from this phase current and the power supply voltage. Then, CPU 4 calculates an amount of correction for the current value determined from the drop voltage value by FS relay 5 connected to power supply line 20 located upstream of inverter circuit 2, based on the current value (estimated current value) flowing through the power supply line 20 and detects an overcurrent with a current value calibrated with the calculated amount of correction as a reference current value. The operation of detecting the overcurrent is repeated with a prescribed timing, and the calibrated current value is updated with the current value at the previous detection timing.

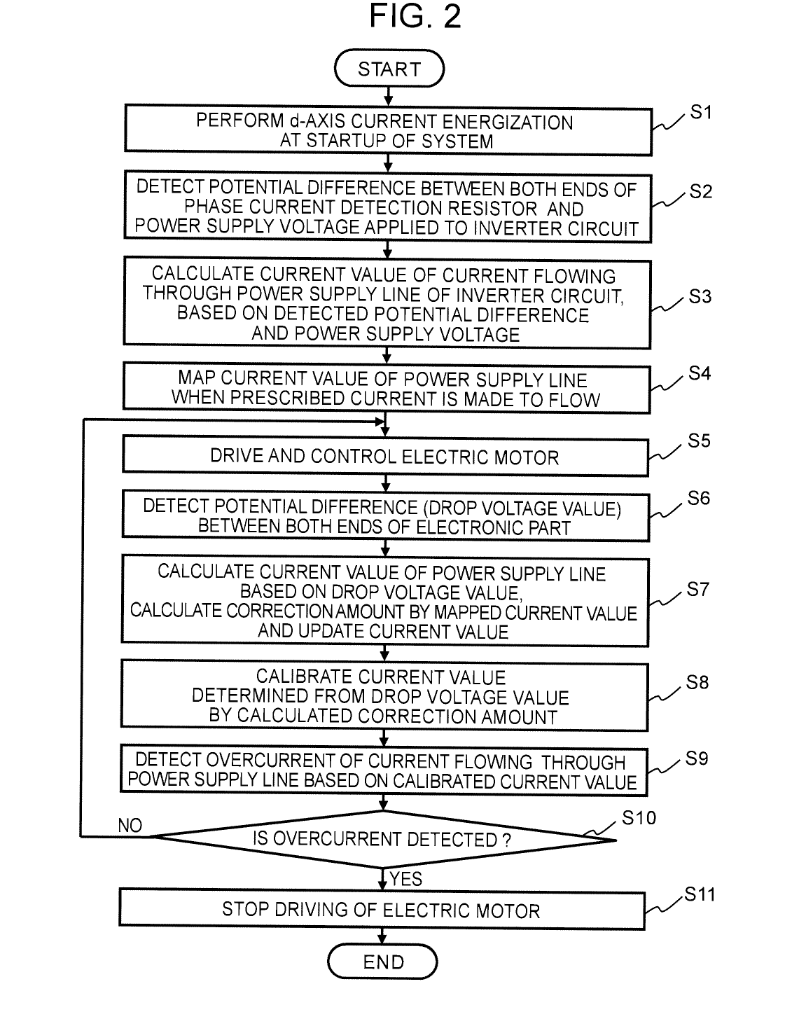

Next, the operation of detecting the overcurrent by the device illustrated in FIG. 1, i.e., an overcurrent detecting method of the present invention, will be described in detail using the flowchart of FIG. 2.

First, when starting up a system that is the drive control device for the electric motor, CPU 4 controls inverter driving IC3 to ON/OFF-control MOSFETs 21 to 26 and thereby perform d-axis current energization on electric motor 1 (Step S1). Next, a difference in potential between both ends of phase current detection resistor 11 when a d-axis current is made to flow in electric motor 1 is detected by operational amplifier 12. Further, the voltage of DC power supply 8 is supplied to CPU 4 by I/F circuit 10, where the power supply voltage is measured (Step S2).

Subsequently, each phase current is calculated by CPU 4 based on the potential difference and the power supply voltage, and the current value of current flowing through power supply line 20 of inverter circuit 2 is calculated from this phase current and the power supply voltage (Step S3).

Then, when a prescribed current is made to flow in electric motor 1, the current value flowing through power supply line 20 of inverter circuit 2 is mapped to a storage device (which may be outside CPU 4) inside CPU 4 (Step S4).

Detecting each phase current is done to estimate this current value from a current value measured in another place because it is unknown whether the voltage drop value detected by FS relay 5 is one at how much current flows in this FS relay 5. Further, since the d-axis current energization is an energizing method that generates torque and does not generate a rotating force, an approximately constant current flows. Thus, CPU 4 is capable of storing in advance as data for calibration, variations in resistance value of FS relay 5, and errors due to changes in characteristics, e.g., a change in timing, a change in temperature, deterioration, etc.

When the drive control of electric motor 1 is started (Step S5), operational amplifier 9 detects a difference in potential (drop voltage value) between both terminals of FS relay 5 (electronic part) located upstream of inverter circuit 2 and supplies it to CPU 4 (Step S6).

In the next Step S7, CPU 4 calculates a current value of power supply line 20, based on the drop voltage value detected in Step S6 and calculates a correction amount using the current value of power supply line 20 mapped in Step S4. Then, the current value mapped in Step S4 is updated with the calculated correction amount.

In Step S8, the current value determined from the drop voltage value is calibrated by the correction amount calculated by CPU 4 in Step S7. This calibration enables the current value determined from the drop voltage value to be made equal to the current value (estimated current value) of power supply line 20 or closer to the estimated current value.

Subsequently, CPU 4 detects the overcurrent of the current flowing through power supply line 20, based on the calibrated current value (Step S9). Upon detection of the overcurrent, it is determined whether, for example, the current value of power supply line 20 is greater than the calibrated current value or the current value set in advance by a prescribed value or more (Step S10). If the current value is greater than that, it is determined to be an overcurrent. When the overcurrent is detected by CPU 4, the driving of electric motor 1 is stopped (Step S11) and finished. When no overcurrent is detected, the overcurrent detecting operation returns to Step S5 where the same operation is repeated.

According to such a configuration as described above, FS relay 5 can be used instead of the shunt resistor by detecting the drop voltage value using existing FS relay (electronic part) 5 for the drive control device installed upstream of inverter circuit 2, detecting each phase current in the downstream of inverter circuit 2 and performing feedback control to calibrate the same. Thus, it is possible to detect the overcurrent, based on the current value determined from the drop voltage value of FS relay 5 at the time of the ground fault in the upstream of inverter circuit 2 without providing the shunt resistor in the upstream of inverter circuit 2.

Also, when the system starts up, the current value obtained when the prescribed current is made to flow in power supply line 20 is mapped and the current value flowing through power supply line 20, which has been determined from the drop voltage value of FS relay 5, is calibrated, thereby making it possible to suppress the influence of variations in the resistance value of the electronic part.

Furthermore, since the current value of power supply line 20 is updated to the current value after calibration, it is possible to suppress the effects of changes in the characteristics of FS relay 5, e.g., a change in resistance value due to a change in a contact position of a relay contact, and a change in temperature, etc. and secure accuracy even if the existing electronic part for the drive control device is used.

Since the overcurrent detecting device of the present invention need not provide the shunt resistor upstream of the inverter circuit as described above, the mounting area and the wiring area can be reduced. There has been a demand for a vehicle ECU to miniaturize a circuit substrate for miniaturization. Since, however, the overcurrent can be detected without using the shunt resistor as described above, it is possible to achieve miniaturization and cost reduction of ECU if it is applied to the drive control device for the vehicle electric motor.

### Second Embodiment

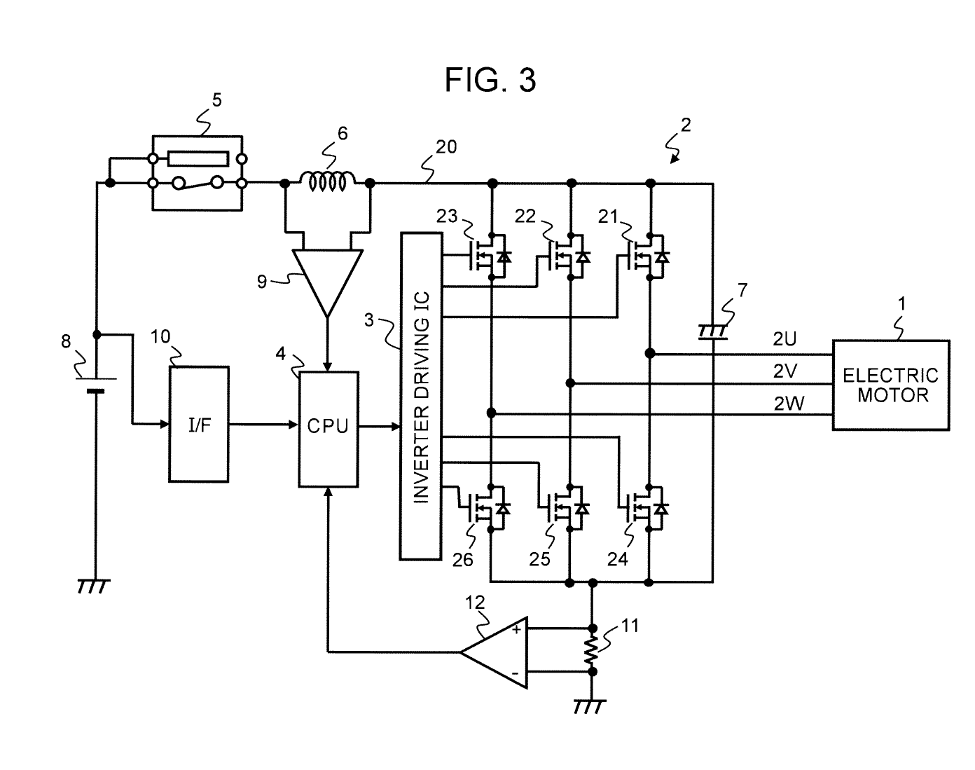

In the second embodiment illustrated in FIG. 3, noise removing coil 6 is used as an electronic part located upstream of inverter circuit 2. First and second input terminals of operational amplifier 9 are connected to both ends of noise removing coil 6 to detect a drop voltage value.

Since other basic configurations are similar to the first embodiment, the same reference numerals are attached to the same parts as FIG. 1 and their detailed description will be omitted.

Even in such a configuration as described above, the second embodiment is basically similar to the first embodiment. An overcurrent can be detected without providing the shunt resistor upstream of inverter circuit 2. Because the shunt resistor is unnecessary, this makes it possible to reduce a mounting area and a wiring area and miniaturize a circuit substrate. Thus, an ECU can be miniaturized and reduced in cost when applied to the drive control device for the vehicle electric motor. Furthermore, the influence of variations in the resistance value of noise removing coil 6 and a change in characteristics, e.g., a change in temperature, etc., can also be suppressed.

In addition, since noise removing coil 6 does not change in resistance value by ON/OFF operation as in a relay, the resistance value is measured in advance and is stored in a storage device. A current value of power supply line 20 may be calculated based on the detected drop voltage value and this resistance value.

The present invention is not limited to the aforementioned first and second embodiments, and it can be modified and embodied in various forms.

For example, in Step S1 of FIG. 2, when the d-axis current energization is done, currents different in current value are made to flow, and data of a straight line connecting current values of two points is used as mapping data to thereby enable high accuracy. Currents having three or more types of different current values are made to flow to associate respective data with each other, whereby higher-accuracy mapping is also made possible.

Also, the prescribed current value is mapped at the startup of the system, but this may be performed when finishing the system.

Further, although description has been made about the case in which the electronic parts for the drive control device are the power supply cutoff part (FS relay) and the noise removing coil, they are not limited thereto, and other existing electronic parts may of course be used.

### REFERENCE SYMBOL LIST

1 . . . electric motor, 2 . . . inverter circuit, 5 . . . FS relay (electronic part), 6 . . . noise removing coil (electronic part), 8 . . . DC power supply, 9, 12 . . . operational amplifier, 10 . . . I/F circuit, 11 . . . phase current detection resistor, 20 . . . power supply line.

1. An overcurrent detecting device for detecting an overcurrent upstream of an inverter circuit in a drive control device for an electric motor, wherein a current value flowing through a power supply line is calculated from each phase current supplied to the electric motor and a power supply voltage of the inverter circuit, and the overcurrent is detected based on a current value determined from a drop voltage value by an electronic part for the drive control device, which is connected to the power supply line, and the current value flowing through the power supply line.

2. The overcurrent detecting device according to claim 1, wherein the current value determined from the drop voltage value by the electronic part is calibrated by the current value flowing through the power supply line, and the current value flowing through the power supply line is updated with the current value after calibration.

3. The overcurrent detecting device according to claim 1, wherein the electronic part is connected between a DC power supply and the power supply line of the inverter circuit.

4. The overcurrent detecting device according to claim 3, wherein the electronic part is a power supply cutoff part that stops the supply of power to the inverter circuit when the electric motor or the drive control device fails, or is a noise removing coil.

5. The overcurrent detecting device according to claim 3, wherein the electronic part includes the power supply cutoff part that stops the supply of power to the inverter circuit when the electric motor or the drive control device fails, and the noise removing coil, and the power supply cutoff part and the noise removing coil are connected in series between the DC power supply and the power supply line of the inverter circuit, and the drop voltage value is detected from one thereof.

6. The overcurrent detecting device according to claim 1, wherein the inverter circuit is a three-phase bridge circuit configuration that drives U, V and W phases of the electric motor for every phase through drive lines respectively.

7. The overcurrent detecting device according to claim 1, further comprising an inverter driving IC that controls the inverter circuit, and a CPU that performs an arithmetic operation and determination for detecting an overcurrent and controls the inverter driving IC.

8. The overcurrent detecting device according to claim 7, further comprising an interface circuit that supplies a voltage of the DC power supply to the CPU, a first operational amplifier that detects the drop voltage value by the electronic part and supplies the same to the CPU, a phase current detection resistor connected between the downstream of the inverter circuit and a ground line, and a second operational amplifier that detects a difference in potential between both ends of the phase current detection resistor and supplies the same to the CPU.

9. An overcurrent detecting method for detecting an overcurrent upstream of an inverter circuit in a drive control device for an electric motor, comprising the steps of:
detecting a drop voltage value by an upstream electronic part for the drive control device in the inverter circuit;
detecting each phase current supplied to the electronic motor and a power supply voltage applied to the inverter circuit;
estimating a current value of a power supply line from the phase current and the power supply voltage;
calculating a correction amount from the drop voltage value and the estimated current value;
correcting a current value determined from the drop voltage by the correction amount; and
detecting the overcurrent on the basis of the current value corrected.

10. The overcurrent detecting method according to claim 9, further comprising a step of calibrating the current value determined from the drop voltage value by the current value flowing through the power supply line and updating the current value flowing through the power supply line with the current value after calibration and wherein an overcurrent of the current flowing through the power supply line is detected based on the calibrated current value.

11. The overcurrent detecting method according to claim 10, wherein the step of calibrating the current value determined from the drop voltage value by the current value flowing through the power supply line and updating the current value flowing through the power supply line with the current value after calibration includes the following steps of:
allowing a prescribed current to flow in the electric motor;
mapping the current value flowing through the power supply line of the inverter circuit to a storage device;
calculating a correction amount using the mapped current value of the power supply line; and
updating the mapped current value with the calculated correction amount.

12. The overcurrent detecting method according to claim 10, wherein the step of calibrating the current value determined from the drop voltage value by the current value flowing through the power supply line and updating the current value flowing through the power supply line with the current value after calibration is repeated at a prescribed timing to update the calibrated current value with the current value at the previous detection timing.

13. The overcurrent detecting method according to claim 9, wherein the step of detecting the overcurrent on the basis of the current value corrected as above determines whether the corrected current value is greater than a set current value, and determines the corrected current value to be an overcurrent when the corrected current value is greater than the set current value.

14. The overcurrent detecting method according to claim 9, further comprising a step of calibrating the current value determined from the drop voltage value by the current value flowing through the power supply line, and a step of updating the current value flowing through the power supply line with the current value after calibration, and wherein the current value of the power supply line is determined whether or not to be greater than the calibrated current value by a prescribed value or more, and determined to be an overcurrent when the current value of the power supply line is greater than that by the prescribed value or more.

15. The overcurrent detecting method according to claim 9, further comprising the following steps of:
performing d-axis current energization on the electric motor when starting up or finishing a system;
detecting a difference in potential between both ends of a phase current detection resistor connected between the inverter circuit and a ground line when a d-axis current is made to flow in the electric motor; and
detecting the power supply voltage applied to the inverter circuit.

16. The overcurrent detecting method according to claim 15, further comprising the following step of:
mapping the current value flowing through the power supply line of the inverter circuit to a storage device.
